(19) United States
(12) Patent Application Publication
(10) Pub. No.: US 2023/0253757 A1
(43) Pub. Date: Aug. 10, 2023

(54) SEMICONDUCTOR LASER MODULE

(71) Applicant: Mitsubishi Electric Corporation, Chiyoda-ku, Tokyo (JP)

(72) Inventor: Daisuke MORITA, Tokyo (JP)

(73) Assignee: Mitsubishi Electric Corporation, Chiyoda-ku, Tokyo (JP)

(21) Appl. No.: 18/003,111

(22) PCT Filed: Aug. 3, 2021
(86) PCT No.: PCT/JP2021/028696

§ 371 Date: Dec. 22, 2022

(30) Foreign Application Priority Data
Aug. 19, 2020 (JP) 2020-138426

(51) Int. Cl. H01S 5/024; H01S 5/023; H01S 5/042

(52) U.S. Cl. CPC H01S 5/02423; H01S 5/023; H01S 5/04256; H01S 5/02469

(57) ABSTRACT

A semiconductor laser module includes: a semiconductor laser element that outputs a laser beam; a sub-mount material that is electrically conductive and bonded to a first surface of the semiconductor laser element; an electrode assembly that is electrically conductive and connected to a second surface of the semiconductor laser element; a conductive wire structure including a plurality of linear members interconnecting the electrode assembly and the second surface; an insulating plate bonded to the electrode assembly; and a cooling block bonded to the sub-mount material and the insulating plate for cooling the semiconductor laser element, wherein the conductive wire structure fixed to the electrode assembly is electrically connected to the semiconductor laser element after the semiconductor laser element, the sub-mount material, and the cooling block are fixed together through bonding materials.

### FIELD

The present disclosure relates to a semiconductor laser module that outputs a laser beam.

### BACKGROUND

One of systems for machining a workpiece to be machined is a laser system for performing laser machining on a workpiece, using multiple semiconductor laser modules that output laser beams. In order to increase the output power of laser beams, the output power of each of the multiple semiconductor laser modules is increased in this laser system. An increase in output power of a semiconductor laser module causes an increase in temperature of a semiconductor laser element of the semiconductor laser module along with an increase in the amount of heat generated in the semiconductor laser module. Such a temperature rise deteriorates initial characteristics related to the output power of the semiconductor laser element. In order to prevent deterioration of the initial characteristics, a proposed semiconductor laser module that takes heat dissipation performance into consideration.

In a semiconductor laser module described in Patent Literature 1, a conductive plate provided with a plurality of protrusions is disposed between a semiconductor laser element and each electrode assembly. Thus, the semiconductor laser module described in Patent Literature 1 causes the electrode assemblies to radiate heat as well as reducing stress between the semiconductor laser element and the conductive plates.

### CITATION LIST

### Patent Literature

Patent Literature 1: Japanese Patent No. 6472683

### SUMMARY

### Technical Problem

For the above-described technique of Patent Literature 1, unfortunately, a conductive plate on the lower surface side of the semiconductor laser element can be bonded to the semiconductor laser element and the electrode assembly only at the protrusions. Accordingly, bonding forces acting between the conductive plate and the semiconductor laser element and between the conductive plate and the electrode assembly are weak. This poses a problem of the displacement of the mounting position of the semiconductor laser element in the semiconductor laser module when an electrode assembly on the upper surface side of the semiconductor laser element is attached to the semiconductor laser element.

The present disclosure has been made in view of the above, and an object of the present disclosure is to obtain a semiconductor laser module capable of preventing the displacement of the mounting position of the semiconductor laser element as well as of improving heat dissipation from the semiconductor laser element.

### Solution to Problem

In order to solve the above-described problem and achieve the object, a semiconductor laser module of the present disclosure comprises: a semiconductor laser element to output a laser beam; a sub-mount material that is electrically conductive and bonded to a first surface of the semiconductor laser element; and an electrode assembly that is electrically conductive and connected to a second surface of the semiconductor laser element, the second surface being opposite to the first surface. The semiconductor laser module of the present disclosure further comprises: a conductive structure including a plurality of linear members having electrical conductivity, the liner members interconnecting the electrode assembly and the second surface; an insulating plate bonded to the electrode assembly; and a cooling block bonded to the sub-mount material for cooling the semiconductor laser element from a side of the first surface, the cooling block being bonded to the insulating plate for cooling the semiconductor laser element from a side of the second surface. The first surface is a surface closer to a light emission point of the semiconductor laser element than the second surface, and is fixed to the sub-mount material via a first bonding material having electrical conductivity. The sub-mount material is fixed to the cooling block via a second bonding material having electrical conductivity. The conductive structure fixed to the electrode assembly is electrically connected to the semiconductor laser element after the semiconductor laser element, the sub-mount material, and the cooling block are fixed together.

### Advantageous Effects of Invention

The semiconductor laser module according to the present disclosure has an effect of preventing the displacement of the mounting position of the semiconductor laser element as well as of improving the heat dissipation from the semiconductor laser element.

### BRIEF DESCRIPTION OF DRAWINGS

FIG. 1 is a cross-sectional view of a semiconductor laser module according to a first embodiment, which illustrates a configuration thereof.

FIG. 2 is a plan view of the semiconductor laser module according to the first embodiment, which illustrates the configuration thereof.

FIG. 3 is a front view of a semiconductor laser element of the semiconductor laser module according to the first embodiment, which illustrates a configuration of the semiconductor laser element.

FIG. 4 is a plan view of the semiconductor laser element of the semiconductor laser module according to the first embodiment, which illustrates the configuration of the semiconductor laser element.

FIG. 5 is a diagram for describing a configuration of a conductive wire structure of the semiconductor laser module according to the first embodiment.

FIG. 6 is a cross-sectional view of the conductive wire structure of the semiconductor laser module according to the first embodiment, which shows a first arrangement example of the conductive wire structure.

FIG. 7 is a cross-sectional view of the conductive wire structure of the semiconductor laser module according to the first embodiment, which shows a second arrangement example of the conductive wire structure.

FIG. 8 is a diagram for describing a method for mounting the semiconductor laser element of the semiconductor laser module according to the first embodiment.

FIG. 9 is a diagram for describing oscillation operation of the semiconductor laser module according to the first embodiment.

FIG. 10 is a cross-sectional view of a semiconductor laser module according to a second embodiment, which illustrates a configuration thereof.

FIG. 11 is a diagram for describing a configuration of a conductive ribbon structure of the semiconductor laser module according to the second embodiment.

FIG. 12 is a cross-sectional view of the conductive ribbon structure of the semiconductor laser module according to the second embodiment, which shows an arrangement example of the conductive ribbon structure.

FIG. 13 is a cross-sectional view of a semiconductor laser module according to a third embodiment, which illustrates a configuration thereof.

FIG. 14 is a diagram for describing a configuration of a conductive wire structure of the semiconductor laser module according to the third embodiment.

FIG. 15 is a cross-sectional view of the conductive wire structure of the semiconductor laser module according to the third embodiment, which shows an arrangement example of the conductive wire structure.

FIG. 16 is a cross-sectional view of a semiconductor laser module according to a fourth embodiment, which illustrates a configuration thereof.

FIG. 17 is a diagram for describing oscillation operation of the semiconductor laser module according to the fourth embodiment.

### DESCRIPTION OF EMBODIMENTS

Embodiments of a semiconductor laser module according to the present disclosure will be hereinafter described in detail with reference to the drawings.

### First Embodiment

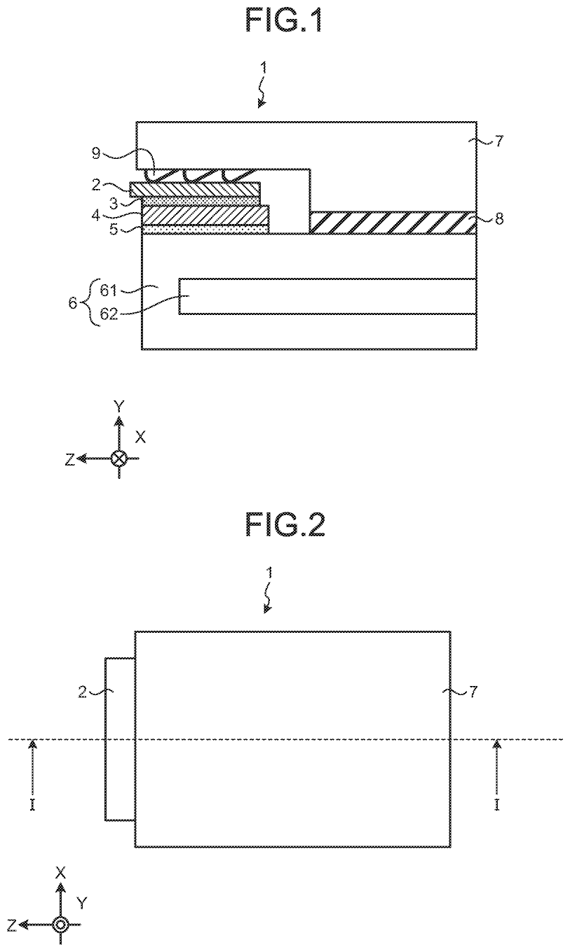

FIG. 1 is a cross-sectional view of a semiconductor laser module according to a first embodiment, which illustrates a configuration thereof. FIG. 2 is a plan view of the semiconductor laser module according to the first embodiment, which illustrates the configuration thereof. FIG. 1 is a view taken in the direction of arrows I-I in FIG. 2. Specifically, FIG. 1 is a cross-sectional view taken along line I-I in FIG. 2.

In the following description, two axes orthogonal to each other in a plane parallel to the upper surface of a semiconductor laser module 1 are defined as an X-axis and a Z-axis. In addition, an axis orthogonal to the X-axis and the Z-axis is defined as a Y-axis. In the first embodiment, a direction in which a laser beam oscillates is defined as a +Z direction, a direction in which the upper surface of the semiconductor laser module 1 faces is defined as a +Y direction, and a direction in which the semiconductor laser module 1 has its depth is defined as a +X direction.

The semiconductor laser module 1 includes a semiconductor laser element 2 that outputs a laser beam. The semiconductor laser element 2 is in a plate shape having an upper surface parallel to an XZ plane. The semiconductor laser element 2 is, for example, a multi-emitter type semiconductor laser element. The following description is made giving an example in which the semiconductor laser element 2 is a multi-emitter type semiconductor laser element, but the semiconductor laser element 2 may be a semiconductor laser element other than the multi-emitter type semiconductor laser element.

The semiconductor laser module 1 includes a cooling block 6 and a sub-mount material 4. The cooling block 6 dissipates heat generated in the semiconductor laser element 2. The cooling block 6 and the sub-mount material 4 each are in a plate shape having an upper surface parallel to the XZ plane. The semiconductor laser element 2 and the sub-mount material 4 are fixed together via a bonding material 3. The sub-mount material 4 and the cooling block 6 are fixed together via a bonding material 5. The bonding materials 3 and 5 are each formed in a plate shape having an upper surface parallel to the XZ plane.

The semiconductor laser module 1 has the bonding material 3 disposed on the upper surface side thereof, and the bonding material 5 disposed on the lower surface side thereof. That is, the bonding material 5 is disposed on a part of the upper surface of the cooling block 6, the sub-mount material 4 is disposed on the upper surface of the bonding material 5, the bonding material 3 is disposed on the upper surface of the sub-mount material 4, and the semiconductor laser element 2 is disposed on the upper surface of the bonding material 3.

The sub-mount material 4 has electrical conductivity. The sub-mount material 4 is made of a material having a linear expansion coefficient close to that of the material of the semiconductor laser element 2. The sub-mount material 4 is made of, for example, copper-tungsten. Furthermore, the surface of the sub-mount material 4 is plated with, for example, Au (gold).

The cooling block 6 includes a base material 61. In addition, the cooling block 6 has a water passage 62 therein. The base material 61 has electrical conductivity. For example, copper is used for the base material 61. The surface of the base material 61 is plated with, for example, Au. The water passage 62 is provided extending in a direction parallel to the XZ plane. Water for cooling flows through the water passage 62.

The bonding materials 3 and 5 have electrical conductivity. The bonding materials 3 and 5 are each desirably a solder material having a melting point of 400° C. or lower. For example, gold-tin solder or tin-silver-copper solder is used for the bonding materials 3 and 5.

In addition, the semiconductor laser module 1 further includes a conductive wire structure 9 and an electrode assembly 7. The conductive wire structure 9 is an example of a conductive structure. The electrode assembly 7 is for applying current to the semiconductor laser element 2. The conductive wire structure 9, which is defined as a first structure, is a group of wires interconnecting the semiconductor laser element 2 and the electrode assembly 7.

The electrode assembly 7 has electrical conductivity. The semiconductor laser module 1 has the electrode assembly 7 disposed on the upper surface side thereof. A gap is provided between the electrode assembly 7 and the semiconductor laser element 2, and the conductive wire structure 9 is disposed in the gap. A detailed configuration of the conductive wire structure 9 will be described later. Note that the water passage 62 for cooling may be provided in the electrode assembly 7. The electrode assembly 7 is made of, for example, copper, and has a surface plated with Au.

In addition, the semiconductor laser module 1 further includes an insulating plate 8 that radiates heat generated by the semiconductor laser element 2 toward the cooling block 6 via the conductive wire structure 9 and the electrode assembly 7. The insulating plate 8 has a plate shape with an upper surface parallel to the XZ plane.

The insulating plate 8 is disposed, for example, in the XZ plane as with the bonding material 5. The insulating plate 8 is disposed in a region where the bonding material 5 is not disposed in the XZ plane. The insulating plate 8 has electrical insulating properties, and has high thermal conductivity. The insulating plate 8 includes, for example, aluminum nitride, silicon nitride, or silicon. Furthermore, the insulating plate 8 has rigidity that prevents electrical insulating performance from being lost even if a thickness of the insulating plate 8 changes due to stress generated when the electrode assembly 7 is attached to the insulating plate 8. In other words, the insulating plate 8 is made of a material having rigidity that allows an amount of change in thickness of the insulating plate 8 to be smaller than a distance between the electrode assembly 7 and the semiconductor laser element 2, the change in thickness being due to stress applied to the insulating plate 8 when the electrode assembly 7 is fixed to the insulating plate 8.

As discussed above, the bonding material 5 and the insulating plate 8 are disposed on the upper surface of the cooling block 6 of the semiconductor laser module 1. In addition, the sub-mount material 4, the bonding material 3, the semiconductor laser element 2, and the conductive wire structure 9 are disposed on the upper surface of the bonding material 5. The electrode assembly 7 is disposed on the upper side of the conductive wire structure 9 and on the upper surface of the insulating plate 8.

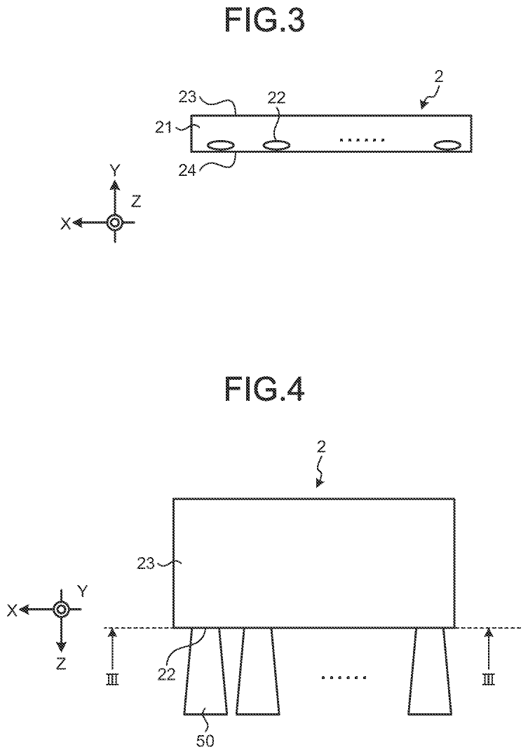

FIG. 3 is a front view of the semiconductor laser element of the semiconductor laser module according to the first embodiment, which illustrates a configuration of the semiconductor laser element. FIG. 4 is a plan view of the semiconductor laser element of the semiconductor laser module according to the first embodiment, which illustrates the configuration of the semiconductor laser element. FIG. 3 is a view taken in the direction of arrows III-III in FIG. 4.

The semiconductor laser element 2 includes a semiconductor substrate 21, a junction surface 24, and a substrate surface 23. The junction surface 24 is defined as a first surface. The substrate surface 23 is defined as a second surface facing the first surface. The substrate surface 23 and the junction surface 24 are surfaces parallel to the XZ plane. Light emission points 22 of laser beams 50 emitted from the semiconductor laser element 2 are located between the substrate surface 23 and the junction surface 24 and are closer to the junction surface 24 than to the substrate surface 23.

The substrate surface 23 is the upper surface of the semiconductor laser element 2, and the conductive wire structure 9 is connected to the substrate surface 23. The junction surface 24 is the lower surface of the semiconductor laser element 2, and the bonding material 3 is disposed on the junction surface 24.

The surfaces of the substrate surface 23 and the junction surface 24 are plated with, for example, Au. For example, the semiconductor substrate 21 that makes a major contribution to the output power of the laser beams 50 of the semiconductor laser element 2 is gallium arsenide. The oscillation output of the semiconductor laser element 2 is, for example, several hundred watts or more.

A detailed configuration of the conductive wire structure 9 will be described. FIG. 5 is a diagram for describing a configuration of the conductive wire structure of the semiconductor laser module according to the first embodiment. FIG. 5 is an enlarged view of the conductive wire structure 9 illustrated in FIG. 1, illustrating schematically the surroundings of the conductive wire structure 9.

The conductive wire structure 9 includes a plurality of conductive wires 91. The conductive wire 91 is an example of a linear member. The conductive wire structure 9 is formed such that each of the plurality of conductive wires 91 is fixed in a loop shape to a contact surface 71 of the electrode assembly 7. Specifically, one end and an opposite end of the conductive wire 91 are bonded to the contact surface 71 at different locations. The conductive wire 91 is bent in a U-shape, and a part of a bent section of the conductive wire 91 is in contact with the substrate surface 23. That is, the conductive wire 91 is bent extending from the contact surface 71 with the one and opposite ends bonded to the contact surface 71. The bent portion of the conductive wire 91 is neither the one end nor the opposite end of the conductive wire 91, and is in contact with the substrate surface 23.

Note that the conductive wire structure 9 may be formed such that each of the plurality of conductive wires 91 is fixed in a loop shape to the substrate surface 23. In this case, the one end and opposite end of the conductive wire 91 are bonded to the substrate surface 23 at different locations, and the bent portion of the conductive wire 91, which is neither the one end nor the opposite end of the conductive wire 91, is in contact with the contact surface 71.

The distance between the contact surface 71 of the electrode assembly 7 and the substrate surface 23 of the semiconductor laser element 2 varies depending on the thickness of the insulating plate 8, that is, the length of the insulating plate 8 in the Y direction. In view of this, the thickness of the insulating plate 8 is set such that the distance between the contact surface 71 and the substrate surface 23 is shorter than the height of the conductive wire 91, which height is the length of the conductive wire 91 in the Y direction. The distance between the contact surface 71 and the substrate surface 23 is set to a distance shorter than the length of the conductive wire 91 in the Y direction. As a result, when the electrode assembly 7 with the conductive wire structure 9 disposed thereon is attached to the semiconductor laser element 2, the conductive wire 91 comes into contact with the semiconductor laser element 2 with the conductive wire 91 further bent.

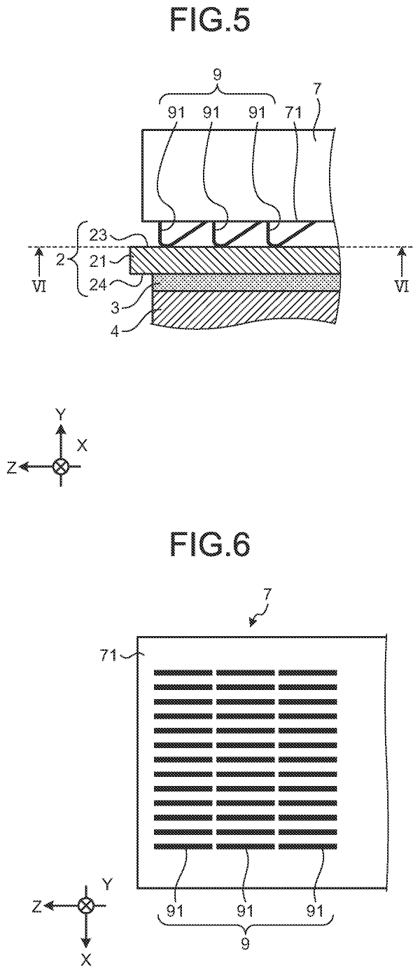

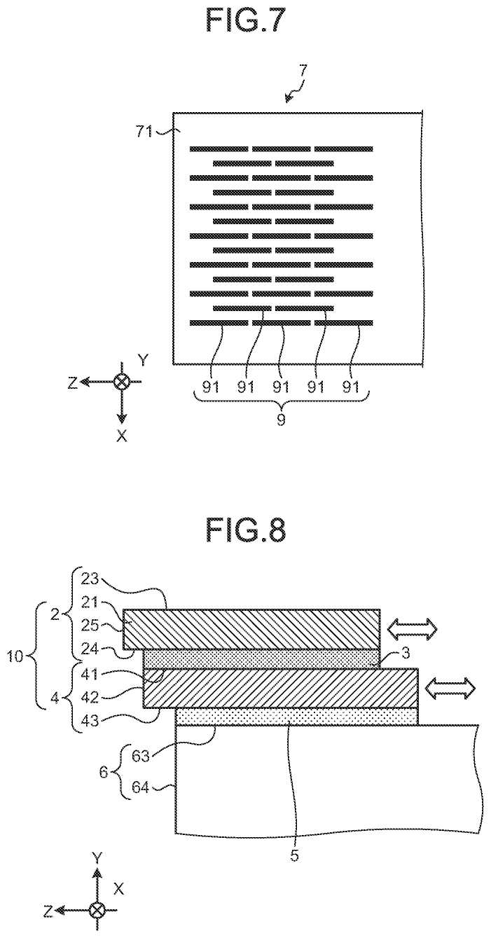

FIG. 6 is a cross-sectional view of the conductive wire structure of the semiconductor laser module according to the first embodiment, which shows a first arrangement example of the conductive wire structure. FIG. 7 is a cross-sectional view of the conductive wire structure of the semiconductor laser module according to the first embodiment, which shows a second arrangement example of the conductive wire structure. FIGS. 6 and 7 are views taken in the direction of arrows VI-VI in FIG. 5.

The contact surface 71 has a rectangular region with sides in the X direction and sides in the Z direction. The conductive wires 91 are arranged such that the longitudinal direction of each conductive wire 91 is the Z direction, when viewed from the X direction. In the conductive wire structure 9, for example, the conductive wires 91 are aligned in both the X direction and the Z direction, as illustrated in FIG. 6. The X direction is defined as a first direction and the Z direction is defined as a second direction. Specifically, the conductive wires 91 are arranged at equal intervals in the X direction such that the conductive wires 91 arranged in the X direction have the same Z-axis coordinates. In addition, the conductive wires 91 are arranged at equal intervals in the Z direction such that the conductive wires 91 arranged in the Z direction have the same X-axis coordinates. That is, the conductive wires 91 are arranged in a matrix in the rectangular region of the contact surface 71 such that the conductive wires 91 are aligned in the X direction and the Z direction. Accordingly, the conductive wires 91 are arranged in N rows and M columns, where N and M are natural numbers.

Furthermore, in the conductive wire structure 9, for example, the conductive wires 91 adjacent in the X direction may be offset from each other in the Z direction, as illustrated in FIG. 7. In this case, the conductive wires 91 are arranged at equal intervals in the X direction such that the conductive wires 91 placed in every other row in the X direction have the same Z-axis coordinates. In addition, the conductive wires 91 are arranged at equal intervals in the Z direction such that the conductive wires 91 arranged in the Z direction have the same X-axis coordinates. That is, the conductive wires 91 are aligned in the X direction and the Z direction in the rectangular region of the contact surface 71 such that the conductive wires 91 adjacent to each other in the X direction are located on different coordinates in the Z direction.

The conductive wire 91 is made of metal having relatively low electric resistance. For example, diffusion bonding between metals is used for fixing the conductive wire 91 to the electrode assembly 7. The conductive wire 91 is made of, for example, gold, copper, or silver. The cross section of the conductive wire 91 is, for example, a circle with ϕ20 to 100 μm. That is, when the conductive wire 91 is cut along a plane perpendicular to its axial direction, the cross section of the conductive wire 91 is a circle having a diameter of 20 to 100 μm. The conductive wires 91 are pressed against the substrate surface 23 of the semiconductor laser element 2 to electrically interconnect the conductive wires 91 and the semiconductor laser element 2.

As described above, in the semiconductor laser module 1, the junction surface 24 of the semiconductor laser element 2 is entirely bonded to the sub-mount material 4 through the bonding material 3, and the substrate surface 23 is electrically connected to the electrode assembly 7 via the conductive wire structure 9. As a result, the semiconductor laser element 2 can radiate heat from both the junction surface 24 and the substrate surface 23. In addition, the semiconductor laser module 1, which has an increased contact area on the low-thermal-resistance side defined by the junction surface 24, can achieve high heat dissipation performance, prevent deterioration of initial characteristics related to output power, and prolong its own life.

In the manufacturing process of the semiconductor substrate 21, a layer is grown on one surface of the semiconductor substrate 21. As a result, each light emission point 22 in the semiconductor laser element 2 is not located in the center of the semiconductor laser element 2 in the thickness direction (Y direction) thereof. For this reason, thermal resistance from the light emission point 22, i.e., a heat source to an electrode surface differs between the upper surface side and the lower surface side of the semiconductor laser element 2. That is, thermal resistance from the light emission point 22 to the upper surface (mounting surface 41 to be described later) of the sub-mount material 4 is higher than thermal resistance from the light emission point 22 to the contact surface 71.

In the first embodiment, the contact area of the mounting surface 41, which is an electrode surface on a side closer to the heat source, and the contact area of the cooling block 6 serving as a cooling source are preferentially increased. For example, if the area of contact between the semiconductor laser element 2 and the mounting surface 41 is reduced to 30 to 80% of the mounting surface 41 as a result of a plurality of protrusions being provided on the mounting surface 41, it is disadvantageous in terms of heat dissipation. The first embodiment is more advantageous in terms of heat dissipation because the area of contact between the semiconductor laser element 2 and the mounting surface 41 is not reduced than when a plurality of protrusions are provided.

Next, a series of assembling steps for assembling the semiconductor laser module 1 will be described. FIG. 8 is a diagram for describing a method for mounting the semiconductor laser element of the semiconductor laser module according to the first embodiment. FIG. 8 illustrates a cross-sectional configuration of the semiconductor laser element 2 etc. in the case of cutting the semiconductor laser module 1 along a YZ plane. FIG. 8 is an enlarged view of the semiconductor laser element 2 illustrated in FIG. 1, schematically illustrating the surroundings of the semiconductor laser element 2.

The sub-mount material 4 has the mounting surface 41, an end surface 42, and a bonding surface 43. The semiconductor laser element 2 includes the semiconductor substrate 21, and has the substrate surface 23, the junction surface 24, and an emission end surface 25. The cooling block 6 has a mounting surface 63 and an end surface 64.

The mounting surface 41, the bonding surface 43, the substrate surface 23, the junction surface 24, and the mounting surface 63 are surfaces parallel to the XZ plane. The emission end surface 25 and the end surfaces 42 and 64 are surfaces parallel to an XY plane.

The mounting surface 41 is the upper surface of the sub-mount material 4, the bonding surface 43 is the lower surface of the sub-mount material 4, and the end surface 42 is a side surface of the sub-mount material 4. The substrate surface 23 is the upper surface of the semiconductor laser element 2, the junction surface 24 is the lower surface of the semiconductor laser element 2, and the emission end surface 25 is a side surface of the semiconductor laser element 2. The mounting surface 63 is the upper surface of the cooling block 6, and the end surface 64 is a side surface of the cooling block 6.

The end surfaces 42 and 64 and the emission end surface 25 are surfaces parallel to the XY plane. The sub-mount material 4 has surfaces parallel to the XY plane, and these surfaces include the end surface 42 located in the +Z direction. The cooling block 6 has surfaces parallel to the XY plane, and these surfaces include the end surface 64 located in the +Z direction. The semiconductor laser element 2 has surfaces parallel to the XY plane, and these surfaces include the emission end surface 25 located in the +Z direction.

To assemble the semiconductor laser module 1, the bonding material 3 is placed on the mounting surface 41 of the sub-mount material 4, and the semiconductor laser element 2 is placed on the upper surface of the bonding material 3. The position of the emission end surface 25 is adjusted in the Z direction relative to the end surface 42 of the sub-mount material 4 to thereby determine the position of the semiconductor laser element 2.

After the positioning of the semiconductor laser element 2 is completed, the bonding material 3 is melted to bond the semiconductor laser element 2 and the sub-mount material 4. The bonding material 3 may be formed on the mounting surface 41 of the sub-mount material 4 in advance, using a vapor deposition method.

Next, the bonding material 5 is placed on the mounting surface 63 of the cooling block 6, and a semiconductor laser subassembly 10 with the semiconductor laser element 2 and the sub-mount material 4 bonded together is placed on the upper surface of the bonding material 5. The position of the end surface 42 of the sub-mount material 4 is adjusted in the Z direction relative to the end surface 64 of the cooling block 6 to thereby determine the position of the semiconductor laser subassembly 10. FIG. 8 illustrates the semiconductor laser subassembly 10 during the process of positioning the semiconductor laser subassembly 10.

After the positioning of the semiconductor laser subassembly 10 is completed, the bonding material 5 is melted to bond the semiconductor laser subassembly 10 and the cooling block 6. As described above, it is possible to mount the semiconductor laser element 2, positioning the semiconductor laser element 2 in the Z direction relative to the cooling block 6. The bonding material 5 may be formed on the mounting surface 63 of the cooling block 6 in advance, using the vapor deposition method. Furthermore, given that the bonding material 5 is melted after the bonding material 3, the bonding material 5 desirably has a melting point lower than that of the bonding material 3.

Next, the plurality of conductive wires 91 is fixed to the electrode assembly 7, thereby forming the conductive wire structure 9. The electrode assembly 7 having the conductive wire structure 9 formed thereon is fixed to the cooling block 6 with the insulating plate 8 interposed therebetween. In this state, the electrode assembly 7 is placed on and fixed to the cooling block 6 with the bent section of each conductive wire 91 in contact with the substrate surface 23. For example, a fastening method using screws, or a bonding material may be used in fixing the electrode assembly 7 to the insulating plate 8.

For the semiconductor laser module 1, as described above, the conductive wire structure 9 fixed to the electrode assembly 7 is electrically connected to the semiconductor laser element 2 after the semiconductor laser element 2, the sub-mount material 4, and the cooling block 6 are fixed together. The position of the semiconductor laser element 2 is not displaced when the electrode assembly 7 is fixed to the insulating plate 8 because the semiconductor laser element 2 has been fixed on the cooling block 6.

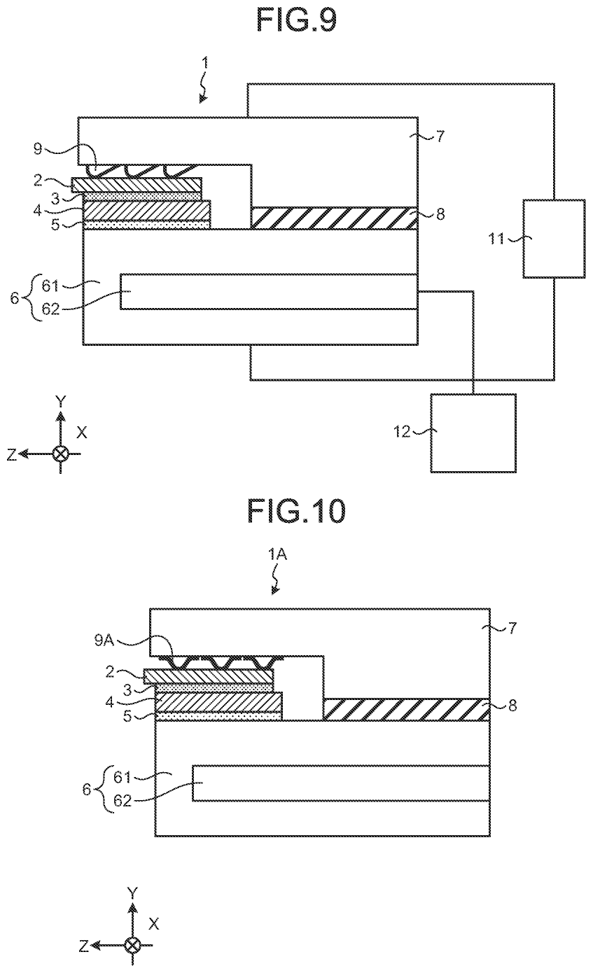

Next, oscillation operation of the semiconductor laser module 1 will be described. FIG. 9 is a diagram for describing oscillation operation of the semiconductor laser module according to the first embodiment. FIG. 9 is a cross-sectional view of the semiconductor laser module 1 taken along the YZ plane. The elements in FIG. 9, which achieve the same functions as those of the semiconductor laser module 1 illustrated in FIG. 1, are denoted by the same reference numerals.

The semiconductor laser module 1 has the electrode assembly 7 connected to one end of a power supply 11, and the cooling block 6 connected to an opposite end of the power supply 11. When the power supply 11 applies a voltage to the semiconductor laser module 1, a current flows through the cooling block 6, the bonding material 5, the sub-mount material 4, the bonding material 3, the semiconductor laser element 2, the conductive wire structure 9, and the electrode assembly 7 in this order to thereby cause the semiconductor laser element 2 to oscillate.

Using a cooling chiller 12, cooling water flows through the water passage 62 of the cooling block 6. As a result, some of heat generated by the semiconductor laser element 2 is dissipated through a path including the bonding material 3, the sub-mount material 4, the bonding material 5, and the cooling block 6, and the rest of heat is dissipated through a path including the conductive wire structure 9, the electrode assembly 7, the insulating plate 8, and the cooling block 6. That is, the cooling block 6 cools the semiconductor laser element 2 from the side of the substrate surface 23, and also cools the semiconductor laser element 2 from the side of the junction surface 24.

As described above, according to the first embodiment, the semiconductor laser element 2 of the semiconductor laser module 1 is fixed to the cooling block 6 via the bonding material 3 and the bonding material 5. When the conductive wire structure 9 and the electrode assembly 7 are attached to the cooling block 6, therefore, the semiconductor laser element 2 does not move. The position of the semiconductor laser element 2 can be therefore accurately determined in the semiconductor laser module.

In addition, since the semiconductor laser element 2 is fixed to the cooling block 6 via the bonding material 3 and the bonding material 5, high heat dissipation performance can be achieved. The semiconductor laser module 1 can therefore prevent the displacement of the mounting position of the semiconductor laser element 2 as well as improving heat dissipation from the semiconductor laser element 2.

In the semiconductor laser module 1, additionally, since the semiconductor laser element 2 and the electrode assembly 7 are connected to each other via the conductive wire structure 9, it is possible to prevent deterioration of a connection portion between the semiconductor laser element 2 and the electrode assembly 7.

In the semiconductor laser module 1, furthermore, since the conductive wire 91 has high flexibility, it is possible to reduce force to be applied to the semiconductor laser element 2 when the conductive wire structure 9 and the electrode assembly 7 are attached to the cooling block 6. That is, stress between the semiconductor laser element 2 and the sub-mount material 4 can be reduced.

### Second Embodiment

Next, a second embodiment will be described with reference to FIGS. 10 to 12. In the second embodiment, a conductive ribbon is used instead of the conductive wire 91.

FIG. 10 is a cross-sectional view of a semiconductor laser module according to the second embodiment, which illustrates a configuration thereof. The elements in FIG. 10, which achieve the same functions as those of the semiconductor laser module 1 of the first embodiment illustrated in FIG. 1, are denoted by the same reference numerals, and redundant description will be omitted.

A semiconductor laser module 1A is different from the semiconductor laser module 1 of the first embodiment in that a conductive ribbon structure 9A is used instead of the conductive wire structure 9. Specifically, in the semiconductor laser module 1A, conductive ribbons (conductive ribbons 91A to be described later) are disposed instead of the conductive wires 91.

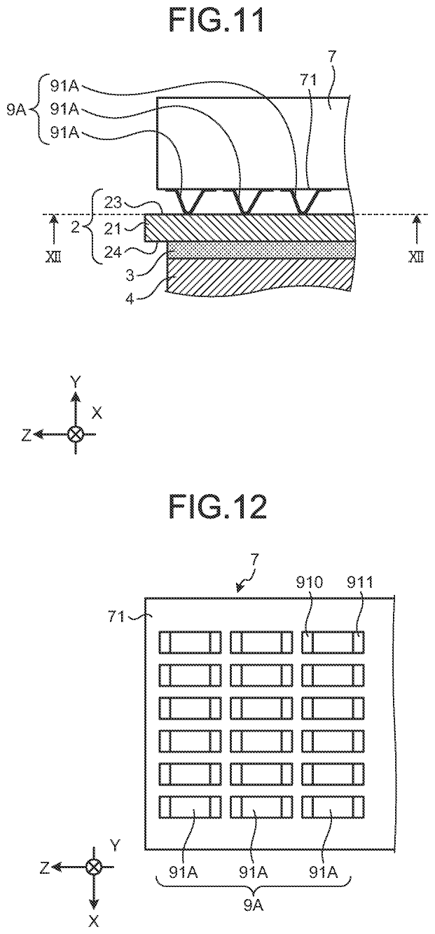

FIG. 11 is a diagram for describing a configuration of the conductive ribbon structure of the semiconductor laser module according to the second embodiment. FIG. 11 is an enlarged view of the conductive ribbon structure 9A illustrated in FIG. 10, schematically illustrating the surroundings of the conductive ribbon structure 9A. The elements in FIG. 11, which achieve the same functions as those of the semiconductor laser module 1 of the first embodiment illustrated in FIG. 5, are denoted by the same reference numerals, and redundant description will be omitted.

The conductive ribbon 91A is made of metal having relatively low electric resistance. For example, diffusion bonding between metals is used for fixing the conductive ribbon 91A to the electrode assembly 7. The conductive ribbon 91A is made of, for example, gold, copper, or silver. The conductive ribbon 91A has a belt shape with a thickness of 50 μm to 200 μm. The cross section of the conductive ribbon 91A is, for example, a rectangle having a width of 0.5 mm to 2.0 mm and a height of 50 μm to 200 μm. That is, when the conductive ribbon 91A is cut along a plane perpendicular to its longitudinal direction, the conductive ribbon 91A has a rectangular cross section.

The conductive ribbon structure 9A is configured such that each of a plurality of the conductive ribbons 91A is fixed in a loop shape to the contact surface 71 of the electrode assembly 7. Specifically, one end 910 (see FIG. 12) and an opposite end 911 (see FIG. 12) of the conductive ribbon 91A are bonded to the contact surface 71 at different locations. The conductive ribbon 91A is bent in a U-shape, and a part of a bent section of the conductive ribbon 91A is in contact with the substrate surface 23. That is, the conductive ribbon 91A is bent extending from the contact surface 71 with the one and opposite ends 910 and 911 bonded to the contact surface 71. The bent portion of the conductive ribbon 91A is neither the one end 910 nor the opposite end 911, and is in contact with the substrate surface 23.

Note that the conductive ribbon structure 9A may be formed such that each of the plurality of conductive ribbons 91A is fixed in a loop shape to the substrate surface 23. In this case, the one end 910 and the opposite end 911 of the conductive ribbon 91A are bonded to the substrate surface 23 at different locations, and the bent portion of the conductive ribbon 91A, which is neither the one end 910 nor the opposite end 911, is in contact with the contact surface 71.

FIG. 12 is a cross-sectional view of the conductive ribbon structure of the semiconductor laser module according to the second embodiment, which shows an arrangement example of the conductive ribbon structure. FIG. 12 is a view taken in the direction of arrows XII-XII in FIG. 11.

The conductive ribbons 91A are arranged such that the longitudinal direction of each conductive ribbon 91A is the Z direction, when viewed from the X direction. In the conductive ribbon 91A, a direction from the one end 910 toward the opposite end 911 is defined as the longitudinal direction. In the conductive ribbon structure 9A, for example, the conductive ribbons 91A are aligned in both the X direction and the Z direction, as illustrated in FIG. 12. Specifically, the conductive ribbons 91A are arranged at equal intervals in the X direction such that the conductive ribbons 91A arranged in the X direction have the same Z-axis coordinates. In addition, the conductive ribbons 91A are arranged at equal intervals in the Z direction such that the conductive ribbons 91A arranged in the Z direction have the same X-axis coordinates. That is, the conductive ribbons 91A are arranged in P rows and Q columns, where P and Q are natural numbers. The conductive ribbons 91A are thus positioned in a manner similar to the conductive wires 91.

Note that in the conductive ribbon structure 9A, the conductive ribbons 91A adjacent in the X direction may be offset from each other in the Z direction, as illustrated in FIG. 7. In this case, the conductive ribbons 91A are arranged at equal intervals in the X direction such that the conductive ribbons 91A placed in every other row in the X direction have the same Z-axis coordinates. In addition, the conductive ribbons 91A are arranged at equal intervals in the Z direction such that the conductive ribbons 91A arranged in the Z direction have the same X-axis coordinates.

The other configuration of the semiconductor laser module 1A than that described with reference to FIGS. 10 to 12 is the same as the configuration of the semiconductor laser module 1 in the first embodiment, and description thereof will be omitted. In addition, a series of assembling steps for assembling the semiconductor laser module 1A and oscillation operation are also similar to those of the semiconductor laser module 1 of the first embodiment, and thus description thereof will be omitted.

As described above, also in the second embodiment, the semiconductor laser element 2 of the semiconductor laser module 1A is fixed to the cooling block 6 via the bonding material 3 and the bonding material 5, as in the first embodiment. Thus, the semiconductor laser module 1A has the same effect as that of the semiconductor laser module 1.

### Third Embodiment

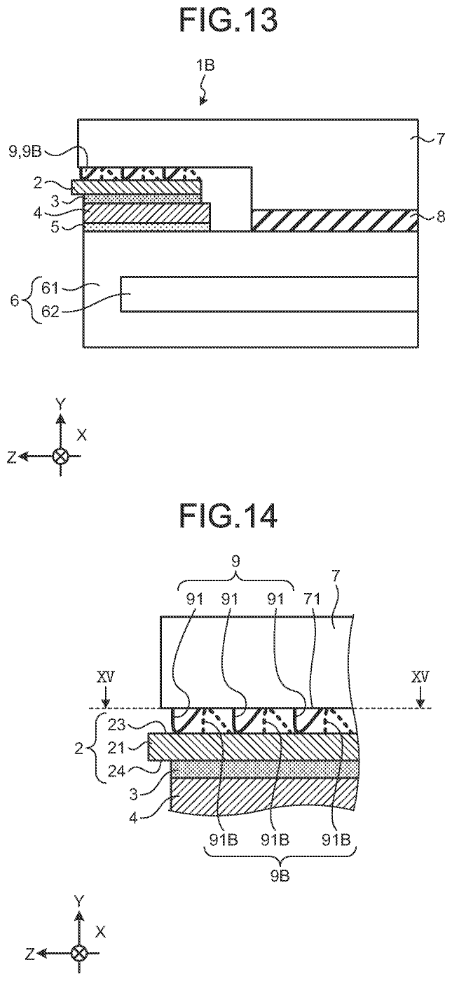

Next, a third embodiment will be described with reference to FIGS. 13 to 15. In the third embodiment, a conductive wire that is the same as the conductive wire 91 is also added onto the substrate surface 23 of the semiconductor laser element 2.

FIG. 13 is a cross-sectional view of a semiconductor laser module according to the third embodiment, which illustrates a configuration thereof. The elements in FIG. 13, which achieve the same functions as those of the semiconductor laser module 1 of the first embodiment illustrated in FIG. 1, are denoted by the same reference numerals, and redundant description will be omitted.

A semiconductor laser module 1B is different from the semiconductor laser module 1 of the first embodiment in that a conductive wire structure 9B is used as a second structure together with the conductive wire structure 9 defined as a first structure. Specifically, conductive wires 91B to be described later are disposed together with the conductive wires 91 in the semiconductor laser module 1B.

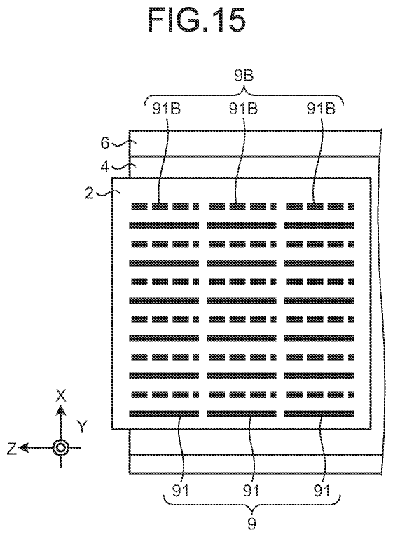

Note that the conductive wires 91 and the conductive wires 91B are schematically illustrated in FIG. 13 and FIG. 14 as will be described later. FIGS. 13 and FIG. 14 as will be described later show that the conductive wire 91 and the conductive wire 91B are alternately arranged when the semiconductor laser module 1B is viewed from the X direction. It is to be noted that the conductive wires 91 and the conductive wires 91B are actually arranged such that the conductive wires 91 and the conductive wires 91B individually have the same X coordinates when the semiconductor laser module 1B is viewed from the X direction. An example of the arrangement of the conductive wire structure 9B will be described later with reference to FIG. 15.

FIG. 14 is a diagram for describing a configuration of the conductive wire structure of the semiconductor laser module according to the third embodiment. FIG. 14 is an enlarged view of the conductive wire structures 9 and 9B illustrated in FIG. 13, schematically illustrating the surroundings of the conductive wire structures 9 and 9B. The elements in FIG. 14, which achieve the same functions as those of the semiconductor laser module 1 of the first embodiment illustrated in FIG. 5, are denoted by the same reference numerals, and redundant description will be omitted.

The conductive wire structure 9 includes a plurality of the conductive wires 91, and the conductive wire structure 9B includes a plurality of the conductive wires 91B. The specifications of the conductive wire 91B are the same as those of the conductive wire 91. That is, the conductive wire 91B and the conductive wire 91 are made of the same material, and have the same shape.

The conductive wire structure 9B is formed such that each of the plurality of conductive wires 91B is fixed in a loop shape to the substrate surface 23 of the semiconductor laser element 2. Specifically, one end and an opposite end of the conductive wire 91B are bonded to the substrate surface 23 at different locations. The conductive wire 91B is bent in a U-shape, and a part of a bent section of the conductive wire 91B is in contact with the contact surface 71. That is, the conductive wire 91B is bent extending from the substrate surface 23 with the one and opposite ends bonded to the substrate surface 23. The bent portion of the conductive wire 91B is neither the one end nor the opposite end of the conductive wire 91B, and is in contact with the contact surface 71.

FIG. 15 is a cross-sectional view of the conductive wire structure of the semiconductor laser module according to the third embodiment, which shows an arrangement example of the conductive wire structure. FIG. 15 is a view taken in the direction of arrows XV-XV in FIG. 14.

The conductive wires 91 and 91B are arranged such that the longitudinal direction of each of the conductive wires 91 and 91B is the Z direction, when viewed from the X direction. In the conductive wire structure 9, for example, the conductive wires 91 are aligned in both the X direction and the Z direction, as illustrated in FIG. 15. Similarly, in the conductive wire structure 9B, for example, the conductive wires 91B are aligned in both the X direction and the Z direction, as illustrated in FIG. 15. The conductive wires 91B are located between the conductive wires 91 arranged in the X direction. In other words, the conductive wires 91 are located between the conductive wires 91B arranged in the X direction.

That is, the conductive wire 91 and the conductive wire 91B are alternately arranged at equal intervals in the X direction such that the conductive wires 91 and 91B arranged in the X direction have the same Z-axis coordinates. In addition, the conductive wires 91 are arranged at equal intervals in the Z direction such that the conductive wires 91 arranged in the Z direction have the same X-axis coordinates. Similarly, the conductive wires 91B are arranged at equal intervals in the Z direction such that the conductive wires 91B arranged in the Z direction have the same X-axis coordinates. That is, the conductive wires 91 are arranged in N rows and M columns, and the conductive wires 91B are arranged in N rows and M columns.

As described above, in the semiconductor laser module 1B, the plurality of conductive wires 91 is fixed to the contact surface 71 of the electrode assembly 7, and the plurality of conductive wires 91B is fixed to the substrate surface 23 of the semiconductor laser element 2. In the process of forming conductive wires, that is, during wire bonding, a gap between wires is made equal to or larger than a wire diameter so as to avoid interference between a bonding tool and a wire adjacent thereto.

Thus, it is possible to arrange the conductive wires 91B between the conductive wires 91, and arrange the conductive wires 91 between the conductive wires 91B by fixing the plurality of conductive wires 91 to the contact surface 71 and fixing the plurality of conductive wires 91B to the substrate surface 23, as in the semiconductor laser module 1B. As a result, in the semiconductor laser module 1B, it is possible to dispose nearly twice as many conductive wires per unit area as those in the semiconductor laser module 1. This improves heat dissipation performance of the semiconductor laser module 1B.

In addition, even in a case where the conductive wire structure 9 and the conductive wire structure 9B partially interfere with each other, heat transfer occurs between the conductive wire structure 9 and the conductive wire structure 9B that interfere with each other. As a result, the number of heat dissipation paths increases as compared with the semiconductor laser module 1, so that heat dissipation performance is improved. Note that FIG. 15 schematically illustrates the arrangement of the conductive wire structures 9 and 9B, but the larger number of the conductive wire structures 9 and 9B than the number of the arranged conductive wire structures 9 illustrated in FIG. 6 are practically arranged.

Note that in the conductive wire structures 9 and 9B, the positions of the conductive wires 91 or the conductive wires 91B may be offset in the Z direction as illustrated in FIG. 7. For example, in the conductive wire structures 9 and 9B, the conductive wires 91B and the conductive wires 91 may be arranged alternately in the XZ plane. In this case, the position of each conductive wire 91B may be shifted in the Z-axis direction but the positions of the conductive wires 91 illustrated in FIG. 15 remains unchanged. Alternatively, the position of each conductive wire 91 may be offset in the Z-axis direction but the positions of the conductive wires 91B illustrated in FIG. 15 remain unchanged.

The other configuration of the semiconductor laser module 1B than that described with reference to FIGS. 13 to 15 is the same as the configuration of the semiconductor laser module 1 in the first embodiment, and description thereof will be omitted. In addition, oscillation operation of the semiconductor laser module 1B is also similar to that of the semiconductor laser module 1 of the first embodiment, and thus description thereof will be omitted.

A series of assembling steps for assembling the semiconductor laser module 1B differs from the series of assembling steps for assembling the semiconductor laser module 1 in the respects as will be discussed hereinbelow. Until the semiconductor laser subassembly 10 and the cooling block 6 are bonded together, the same steps as those in the first embodiment are performed.

Thereafter, the plurality of conductive wires 91B is fixed on the substrate surface 23 of the semiconductor laser element 2. As a result, the conductive wire structure 9B is formed. In addition, the plurality of conductive wires 91 is fixed to the electrode assembly 7. As a result, the conductive wire structure 9 is formed. Then, the electrode assembly 7 is fixed to the cooling block 6 through a process similar to that of the first embodiment.

As described above, also in the third embodiment, the semiconductor laser element 2 of the semiconductor laser module 1B is fixed to the cooling block 6 via the bonding material 3 and the bonding material 5, as in the first embodiment. Thus, the semiconductor laser module 1B has the same effect as that of the semiconductor laser module 1.

Furthermore, the conductive wire structure 9 and the conductive wire structure 9B serve as heat dissipation paths from the substrate surface 23 of the semiconductor laser element 2 to the contact surface 71 of the electrode assembly 7, so that heat is conducted not only via the conductive wire structure 9 but also via the conductive wire structure 9B. As a result, heat dissipation performance is improved as compared with the semiconductor laser module 1 of the first embodiment.

### Fourth Embodiment

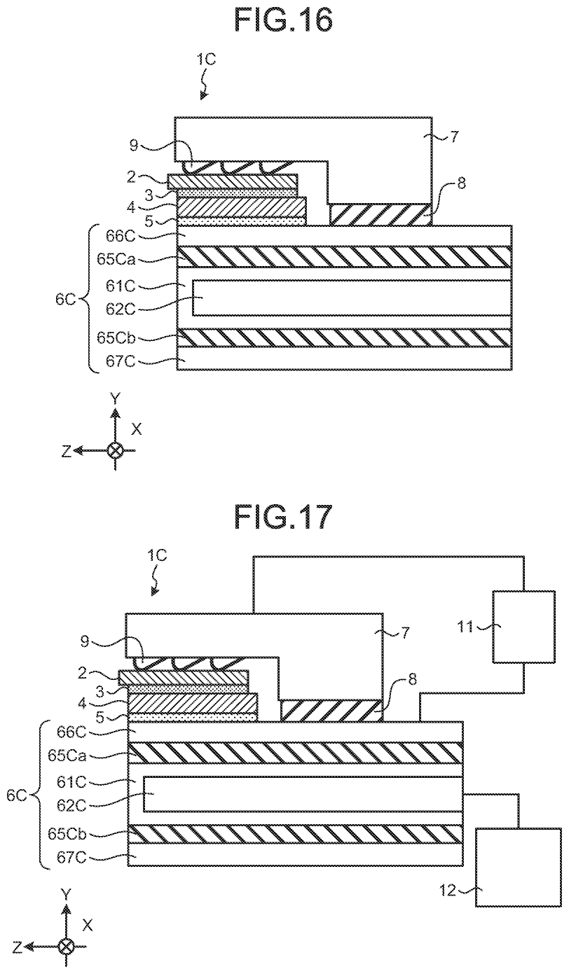

Next, a fourth embodiment will be described with reference to FIGS. 16 and 17. In the fourth embodiment, an electrically insulating heat sink 6C is used instead of the cooling block 6. The electrically insulating heat sink 6C is another example of the cooling block.

FIG. 16 is a cross-sectional view of a semiconductor laser module according to the fourth embodiment, which illustrates a configuration thereof. The elements in FIG. 16, which achieve the same functions as those of the semiconductor laser module 1 of the first embodiment illustrated in FIG. 1, are denoted by the same reference numerals, and redundant description will be omitted.

A semiconductor laser module 1C is different from the semiconductor laser module 1 of the first embodiment in that the electrically insulating heat sink 6C, which is another example of the cooling block, is used instead of the cooling block 6.

The electrically insulating heat sink 6C includes five layers made up of a top layer 66C, an insulating layer 65Ca, a center layer 61C, an insulating layer 65Cb, and a bottom layer 67C. In addition, the electrically insulating heat sink 6C has a water passage 62C in the center layer 61C. The water passage 62C is the same as the water passage 62 described with reference to FIG. 1.

The insulating layer 65Cb, which is a lower insulating layer, is disposed on the upper layer side of the bottom layer 67C. The center layer 61C is disposed on the upper layer side of the lower insulating layer 65Cb. In addition, the insulating layer 65Ca, which is an upper insulating layer, is disposed on the upper layer side of the center layer 61C. The top layer 66C is disposed on the upper layer side of the upper insulating layer 65Ca.

The top layer 66C and the water passage 62C are electrically insulated by the upper insulating layer 65Ca. In addition, the bottom layer 67C and the water passage 62C are electrically insulated by the lower insulating layer 65Cb.

A material that has high thermal conductivity and is electrically conductive is used for each of the top layer 66C, the center layer 61C, and the bottom layer 67C. For example, copper, copper-tungsten, or copper-diamond is used for the top layer 66C, the center layer 61C, and the bottom layer 67C. A material having high thermal conductivity and electrical insulating properties is used for the insulating layers 65Ca and 65Cb. For example, aluminum nitride, silicon nitride, or silicon carbide is used for the insulating layers 65Ca and 65Cb.

The other configuration of the semiconductor laser module 1C than that described with reference to FIG. 16 is the same as the configuration of the semiconductor laser module 1 in the first embodiment, and description thereof will be omitted. In addition, a series of assembling steps for assembling the semiconductor laser module 1C is also similar to that of the semiconductor laser module 1 of the first embodiment, and thus description thereof will be omitted.

Next, oscillation operation of the semiconductor laser module 1C will be described. FIG. 17 is a diagram for describing oscillation operation of the semiconductor laser module according to the fourth embodiment. FIG. 17 is a cross-sectional view of the semiconductor laser module 1C taken along the YZ plane. The elements in FIG. 17, which achieve the same functions as those of the semiconductor laser module 1C illustrated in FIG. 16, are denoted by the same reference numerals.

The semiconductor laser module 1C has the electrode assembly 7 connected to one end of the power supply 11, and the top layer 66C of the electrically insulating heat sink 6C connected to an opposite end of the power supply 11. When the power supply 11 applies a voltage to the semiconductor laser module 1C, a current flows through the top layer 66C, the bonding material 5, the sub-mount material 4, the bonding material 3, the semiconductor laser element 2, the conductive wire structure 9, and the electrode assembly 7 in this order to thereby cause the semiconductor laser element 2 to oscillate.

Using the cooling chiller 12, cooling water flows through the water passage 62C of the cooling block 6 of the electrically insulating heat sink 6C. As a result, some of heat generated by the semiconductor laser element 2 is dissipated through a path including the bonding material 3, the sub-mount material 4, the bonding material 5, and the electrically insulating heat sink 6C, and the rest of heat is dissipated through a path including the conductive wire structure 9, the electrode assembly 7, the insulating plate 8, and the electrically insulating heat sink 6C.

As described above, also in the fourth embodiment, the semiconductor laser element 2 of the semiconductor laser module 1C is fixed to the electrically insulating heat sink 6C via the bonding material 3 and the bonding material 5, as in the first embodiment. Thus, the semiconductor laser module 1C has the same effect as that of the semiconductor laser module 1.

Furthermore, since the semiconductor laser module 1C includes the electrically insulating heat sink 6C, no voltage is applied to the water passage 62C. It is therefore possible to prevent electrolytic corrosion from occurring when cooling water flows through the water passage 62C, and thus possible to prolong the life of the electrically insulating heat sink 6C. As a result, the life of the semiconductor laser module 1C can be prolonged as compared with the semiconductor laser module 1 of the first embodiment.

The configurations set forth in the above embodiments show examples, and it is possible to combine the configurations with another known technique or combine the embodiments with each other, and is also possible to partially omit or change the configurations without departing from the scope of the present disclosure.

### REFERENCE SIGNS LIST

1, 1A to 1C semiconductor laser module; 2 semiconductor laser element; 3, 5 bonding material; 4 sub-mount material; 6 cooling block; 6C electrically insulating heat sink; 7 electrode assembly; 8 insulating plate; 9, 9B conductive wire structure; 9A conductive ribbon structure; 10 semiconductor laser subassembly; 11 power supply; 12 cooling chiller; 21 semiconductor substrate; 22 light emission point; 23 substrate surface; 24 junction surface; 25 emission end surface; 41, 63 mounting surface; 42, 64 end surface; 43 bonding surface; 50 laser beam; 61 base material; 61C center layer; 62, 62C water passage; 65Ca, 65Cb insulating layer; 66C top layer; 67C bottom layer; 71 contact surface; 91, 91B conductive wire; 91A conductive ribbon; 910 one end; 911 opposite end.

1. A semiconductor laser module comprising:
a semiconductor laser element to output a laser beam;
a sub-mount material that is electrically conductive and bonded to a first surface of the semiconductor laser element;
an electrode assembly that is electrically conductive and connected to a second surface of the semiconductor laser element, the second surface being opposite to the first surface;
a conductive structure including a plurality of linear members having electrical conductivity, the liner members interconnecting the electrode assembly and the second surface;
an insulating plate bonded to the electrode assembly; and
a cooling block bonded to the sub-mount material for cooling the semiconductor laser element from a side of the first surface, the cooling block being bonded to the insulating plate for cooling the semiconductor laser element from a side of the second surface, wherein
the first surface is a surface closer to a light emission point of the semiconductor laser element than the second surface, and is fixed to the sub-mount material via a first bonding material having electrical conductivity,
the sub-mount material is fixed to the cooling block via a second bonding material having electrical conductivity,
the conductive structure fixed to the electrode assembly is electrically connected to the semiconductor laser element after the semiconductor laser element, the sub-mount material, and the cooling block are fixed together, and
the conductive structure includes a first structure having the linear members bent with one and an opposite end of each of the linear members bonded to the electrode assembly such that the linear members are each fixed in a loop shape to the electrode assembly, the first structure being in contact with the second surface at bent portions of the linear members fixed to the electrode assembly.

2. (canceled)

3. The semiconductor laser module according to claim 1, wherein
the linear members are bonded to a contact surface of the electrode assembly, the contact surface having a rectangular region having sides in a first direction and sides in a second direction perpendicular to the first direction, and
the linear members are arranged in a matrix in the rectangular region such that the linear members are aligned in the first direction and the second direction.

4. The semiconductor laser module according to claim 1, wherein
the linear member is gold, copper, or silver.

5. The semiconductor laser module according to claim 1, wherein
the linear member has a circular cross section with a diameter of 20 μm to 100 μm when cut along a plane perpendicular to an axial direction of the liner member.

6. The semiconductor laser module according to claim 1, wherein
the conductive structure includes a second structure having the linear members bent with one and an opposite ends of each of the linear members bonded to the second surface such that the linear members are each fixed in a loop shape to the second surface, the second structure being in contact with the electrode assembly at bent portions of the linear members fixed to the second surface.

7. The semiconductor laser module according to claim 1, wherein
the linear members are bonded to a contact surface of the electrode assembly, the contact surface having a rectangular region having sides in a first direction and sides in a second direction perpendicular to the first direction, and
the linear members are aligned in the first direction and the second direction in the rectangular region such that the linear members adjacent to each other in the first direction are located on different coordinates in the second direction.

8. The semiconductor laser module according to claim 1, wherein
the cooling block is an electrically insulating heat sink including a water passage and an insulating layer, cooling water flowing through the water passage, the insulating layer insulating the water passage from a top layer having the sub-mount material placed thereon.

9. The semiconductor laser module according to claim 1, wherein
the linear member is a wire.

10. The semiconductor laser module according to claim 1, wherein
the linear member is a belt-shaped ribbon.

11. The semiconductor laser module according to claim 3, wherein
the insulating plate has a thickness set such that a distance between the contact surface of the electrode assembly and the second surface is shorter than a height of the linear member.

12. The semiconductor laser module according to claim 1, wherein
the insulating plate is made of a material having rigidity that allows an amount of change in thickness of the insulating plate to be smaller than a distance between the electrode assembly and the semiconductor laser element, the change in thickness being due to stress applied to the insulating plate when the electrode assembly is fixed to the insulating plate.

13. The semiconductor laser module according to claim 1, wherein
the insulating plate includes aluminum nitride, silicon nitride, or silicon.

14. The semiconductor laser module according to claim 1, wherein
the electrode assembly is fastened via the insulating plate to the cooling block, using a screw.
